(19) United States
(12) Patent Application Publication
(10) Pub. No.: US 2025/0248142 A1
(43) Pub. Date: Jul. 31, 2025

(54) PHOTODETECTOR WITH SERIES CAPACITOR

(71) Applicant: Marvell Asia Pte Ltd, Singapore (SG)

(72) Inventor: Masaki KATO, Palo Alto, CA (US)

(21) Appl. No.: 19/043,173

(22) Filed: Jan. 31, 2025

Related U.S. Application Data
(60) Provisional application No. 63/627,768, filed on Jan. 31, 2024.

(51) Int. Cl. H10F 39/10; H04B 10/60; H10F 30/223; H10F 71/00; H10F 77/00; H10F 77/122; H10F 77/40

(52) U.S. Cl. CPC H10F 39/103; H10F 30/223; H10F 71/1212; H10F 77/122; H10F 77/413; H10F 77/953; H04B 10/60

(57) ABSTRACT

An optical communication receiver includes: a photodiode and signal processing circuitry coupled to the photodiode. The photodiode is configured to receive a modulated optical signal conveying data and convert the modulated optical signal to an electrical signal. The photodiode includes: a waveguide configured to receive the modulated optical signal; an absorption region above the waveguide; and a capacitor electrically coupled in series with the absorption region to reduce a capacitance of the photodiode as compared to a scenario in which the capacitor is omitted from the photodiode. The signal processing circuitry is configured to process the electrical signal to extract and output the data.

### CROSS REFERENCES TO RELATED APPLICATIONS

This application claims the benefit of U.S. Provisional Patent App. No. 63/627,768, entitled “High-Speed Photodetector with Series Capacitor,” filed on Jan. 31, 2024, which is incorporated herein by reference in its entirety for all purposes.

### FIELD OF TECHNOLOGY

The present disclosure relates generally to optical communication technology, and more particularly to high-speed photodetectors and high-speed photodiodes.

### BACKGROUND

The approaches described in this background section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Networking speed requirements are evolving rapidly. In the early days of the Internet, for example, popular applications were limited to email, bulletin boards, and mostly informational and text-based web page surfing, and the amount of data transferred was usually relatively small as compared to today. Now, Internet and mobile communication applications demand an extremely large amount of bandwidth (as compared to even 15 years ago) for transferring photo, video, music, and other multimedia files. For example, some popular social media networks generates about 4 petabytes (PB) of data daily. As a result of ever increasing communication bandwidth needs, existing data communication systems must continually increase their capacity.

Optical communication is a significant technological area that is growing to address the increasing bandwidth demands of communication networks. Silicon photonics (SiPho) is becoming more prevalent and promises ease of fabrication and compact form factors for optical communication systems.

In SiPho optical communication devices that use waveguide photodiodes (PDs), one impediment to increasing transmission speed is the bandwidth limitations of the waveguide PDs. A photodiode is a type of photodetector that uses a semiconductor to converts light into an electrical signal, while a photodetector is a general term for a device that converts light into an electrical signal.

### SUMMARY

In an embodiment, an optical communication receiver comprises: a photodiode configured to receive a modulated optical signal conveying data and convert the modulated optical signal to an electrical signal. The photodiode includes: a waveguide configured to receive the modulated optical signal; an absorption region above the waveguide; and a capacitor electrically coupled in series with the absorption region to reduce a capacitance of the photodiode as compared to a scenario in which the capacitor is omitted from the photodiode. The optical communication receiver further comprises signal processing circuitry coupled to the photodiode, the signal processing circuitry configured to process the electrical signal to extract and output the data.

In another embodiment, q photodiode for converting a modulated optical signal conveying data to an electrical signal comprises: a waveguide configured to receive the modulated optical signal; an absorption region above the waveguide; and a capacitor electrically coupled in series with the absorption region to reduce a capacitance of the photodiode as compared to a scenario in which the capacitor is omitted from the photodiode.

In yet another embodiment, a method for manufacturing a photodiode includes: fabricating a waveguide on a semiconductor substrate, the waveguide configured to receive a modulated optical signal that conveys data; fabricating an absorption region above the waveguide; and fabricating a capacitor that is electrically coupled in series with the absorption region to reduce a capacitance of the photodiode as compared to a scenario in which the capacitor is omitted from the photodiode.

### BRIEF DESCRIPTION OF THE DRAWINGS

FIG. 1 is a simplified block diagram of an example optical communication receiver that includes a waveguide photodiode (PD) having a capacitor in series with a P-I-N diode to increase a carrier transport bandwidth of the waveguide PD, according to an embodiment.

FIGS. 2A-B are simplified block diagrams of an example waveguide PD that is included in the optical communication receiver of FIG. 1, according to an embodiment.

FIG. 2C is a simplified block diagram of another example waveguide PD that is included in the optical communication receiver of FIG. 1, according to another embodiment.

FIG. 3 is a flow diagram of an example method for manufacturing a waveguide PD such as the example waveguide PD of FIGS. 2A-B and/or the example waveguide PD of FIG. 2C, according to an embodiment.

### DETAILED DESCRIPTION

Silicon photonics (SiPho) waveguide photodiodes (PDs) typically include a germanium (Ge) light absorption region over a silicon (Si) waveguide, which along with a doped layer over the Ge light absorption region form a P-I-N diode. The bandwidth f of such PDs can be modeled as:

$$\frac{1}{{f}^{2}} = \frac{1}{{f}_{LRC}^{2}} + \frac{1}{{f}_{tr}^{2}} \qquad Equation 1$$

where f_{LRC} is an inductance (L), resistance (R), capacitance (C) bandwidth of the waveguide PD, and f_{TR} is a carrier transport bandwidth of the waveguide PD. The f_{LRC} bandwidth is based on an RC time constant of a series resistance of the waveguide PD and a junction capacitance of the waveguide PD. The carrier transport bandwidth f_{TR} is limited by a thickness of the Ge light absorption region, which determines a carrier transport time across the P-I-N diode. In particular, the carrier transport bandwidth f_{TR} is inversely proportional to the thickness of the Ge light absorption region.

Increasing the carrier transport bandwidth f_{TR} helps to increase the bandwidth f of the waveguide PD, and thus decreasing the thickness of the Ge light absorption region helps to increase the carrier transport bandwidth f_{TR}. Decreasing the thickness of the Ge light absorption region, however, increases a junction capacitance of the waveguide PD, which decreases the LCR bandwidth f_{LRC}. To counteract the increase of the junction capacitance when the thickness of the Ge light absorption region is reduced, a length of the Ge light absorption region and/or a width of the Ge light absorption region can be reduced. But decreasing the length and/or the width of the Ge light absorption region sacrifices responsivity of the waveguide PD with regard to light-to-current conversion. In particular, because the length and/or the width of the Ge light absorption region is reduced, there is less area available to absorb light and/or there is less area available for connection to a metal layer.

In embodiments of waveguide PDs described herein, a thickness of a light absorption region is reduced as compared to other implementations, which helps to increase the carrier transport bandwidth f_{TR}. Additionally, to reduce the capacitance of the waveguide PD, a capacitor is provided in series with a P-I-N diode of the waveguide PD, in some embodiments. At least in some embodiments, to improve responsivity of the waveguide PD with regard to light-to-current conversion, the silicon waveguide optionally is configured as a multi-mode interference (MMI) waveguide that focuses received light in a region of the MMI waveguide below the absorption region.

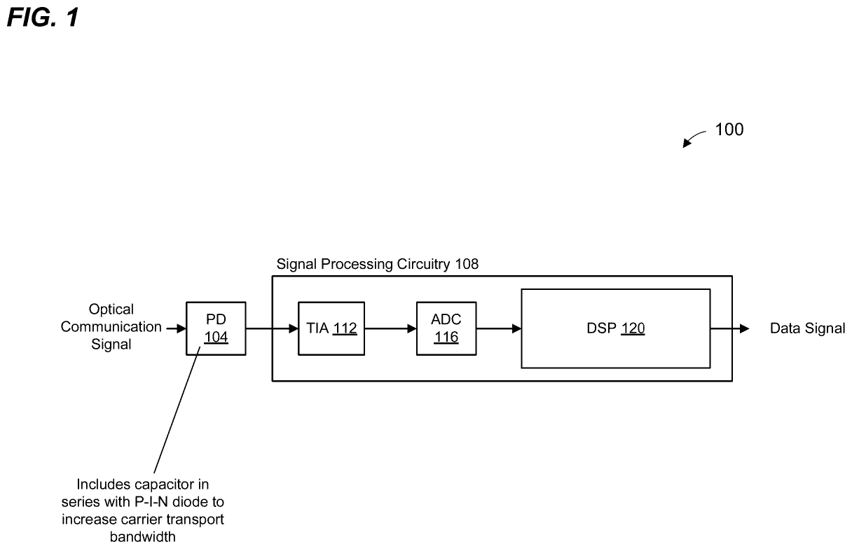

FIG. 1 is a simplified block diagram of an example optical communication receiver 100 that includes a waveguide PD having a capacitor in series with a P-I-N diode to increase a carrier transport bandwidth of the waveguide PD, according to an embodiment. The optical receiver 100 includes as a waveguide PD 104 coupled to signal processing circuitry 108. The signal processing circuitry 108 comprises a trans-impedance amplifier (TIA) 112, an analog-to-digital converter (ADC) 116, and a digital signal processing circuitry (DSP) 120, coupled in series.

The optical communication receiver 100 receives, via an optical communication medium such as optical fiber, free space, etc. a modulated optical wave conveying data. The waveguide PD 104 is configured to absorbs optical energy from the modulated optical wave and converts the optical energy to an analog electrical signal.

The signal processing circuitry 108 is configured to process the analog electrical signal to demodulate data so as to extract and output the data as an output data signal. For example, the TIA 112 converts the analog electrical signal output by the waveguide PD 104 from a current signal to an analog voltage signal. The ADC 116 converts the analog voltage signal to a digital signal, and the DSP 120 processes the digital signal to demodulate data signal to extract and output the data as the output data signal.

As briefly discussed above, the waveguide PD 104 includes a P-I-N diode and a capacitor in series with the P-I-N diode. A thickness of the P-I-N diode is reduced as compared to other implementations, which helps to increase the carrier transport bandwidth of the waveguide PD. Because decreasing the thickness of the P-I-N diode increases a junction capacitance of the waveguide PD (which tends to decrease the bandwidth of the P-I-N diode) the capacitor is provided in series with the P-I-N diode, which reduces the overall capacitance of the waveguide PD (and thus counteracts the negative bandwidth effect of the increased junction capacitance caused by the decreased thickness of the P-I-N diode), according to an embodiment.

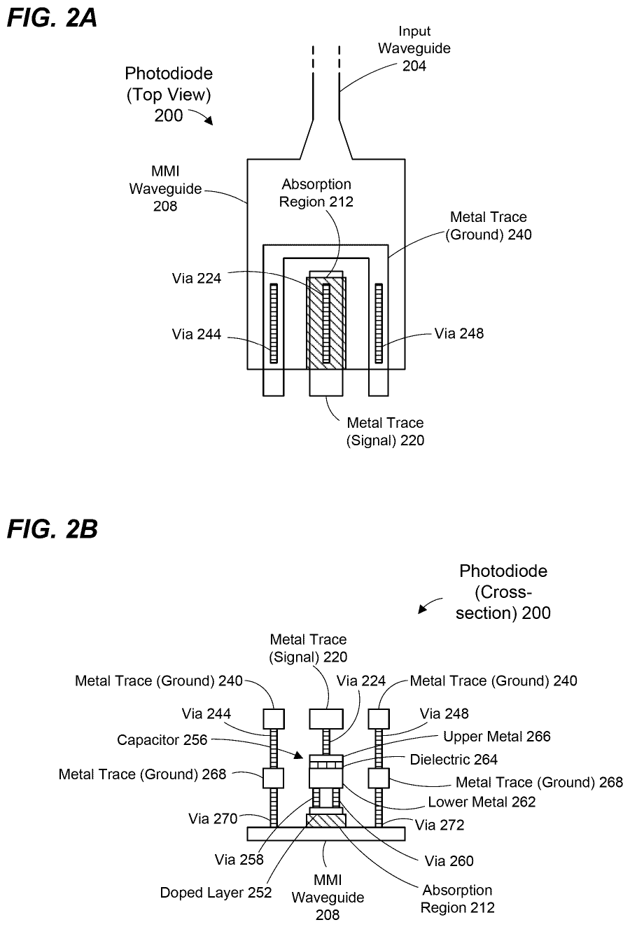

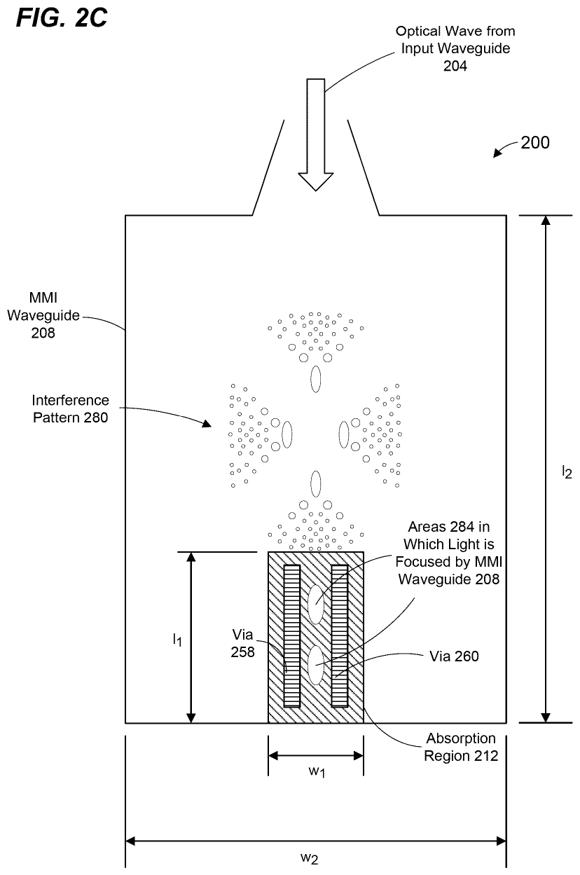

FIG. 2A is a simplified block diagram (top view) of an example waveguide PD 200, according to an embodiment. The waveguide PD 200 is included in the waveguide PD 104 of FIG. 1, according to an embodiment. The waveguide PD 200 is included in another suitable optical communication device different than the optical receiver 100 of FIG. 1, according to another embodiment. In another embodiment, the optical receiver 100 includes another suitable waveguide different than the waveguide PD 200.

Some layers and/or components of the waveguide PD 200 are not shown in FIG. 2A to avoid obscuring elements of the waveguide PD 200 that are present in FIG. 2A.

The waveguide PD 200 is formed on a suitable semiconductor substrate (not shown) such as a silicon-on-insulator (SOI) substrate. The waveguide PD 200 includes an input waveguide 204 optically coupled to a waveguide 208. The input waveguide 204 conveys a modulated optical wave (received via an optical medium such as an optical fiber, free space, etc.) to the waveguide 208. The input waveguide 204 and the waveguide 208 comprise a silicon (Si) material or another suitable material.

An absorption region 212 is formed over the waveguide 208. The absorption region 212 comprises a suitable semiconductor material, such as germanium (Ge) or another suitable material, that is configured to absorb optical energy from the waveguide 208 through evanescent coupling, for example, between the absorption region 212 and the waveguide 208.

A metal trace 220 (sometimes referred to as the “electrode 220”) is formed over the absorption region 212 and is electrically coupled to the absorption region 212 by a via 224, which comprises a suitable electrically conductive material such as metal.

One or more metal traces 240 (sometimes referred to as the “electrode 240”) are formed over the waveguide 208 and are electrically coupled to the waveguide 208 by vias 244, 248. The one or more electrodes 240 correspond to a reference (e.g., ground) voltage and the waveguide 208 is electrically coupled to the reference voltage through the vias 244, 248. The vias 244, 248 comprise a suitable electrically conductive material such as metal.

The electrode 220 corresponds to the electrical signal output by the waveguide PD 200. The electrode 220 and the one or more electrodes 240 are laterally spaced apart within a same layer, according to an embodiment.

FIG. 2B is a simplified diagram of the waveguide PD 200 of FIG. 2A showing a cross-sectional view, according to an embodiment. A doped layer 252 is formed over the absorption region 212. The doped layer 252 has an opposite doping (n-doping vs. p-doping) as compared to the waveguide 208. For example, the doped layer 252 comprises an n-doped material whereas the waveguide 208 comprises a p-doped material, in an embodiment. As another example, the doped layer 252 comprises a p-doped material whereas the waveguide 208 comprises an n-doped material, in another embodiment. The doped layer 252 comprises an Si material or another suitable material.

The doped layer 252, the absorption region 212, and the waveguide 208 form a P-I-N diode. In operation, light absorbed by the absorption region 212 affects a current flow through the P-I-N diode. For example, the P-I-N diode is configured to output an electrical signal in response to optical energy absorbed by the absorption region 212 from the waveguide 208, in an embodiment.

A thickness of the P-I-N diode is reduced as compared to other implementations, which helps to increase the carrier transport bandwidth of the waveguide PD 200.

The doped layer 252 is electrically connected to a capacitor 256 through vias 258, 260, which comprise a suitable electrically conductive material such as metal.

The capacitor 256 comprises a metal-insulator-metal (MIM) capacitor, in an embodiment. The capacitor 256 comprises a lower metal layer 262, a dielectric 264, and an upper metal layer 266. In another embodiment, the capacitor 256 comprises a metal-oxide-metal (MOM) capacitor. In other embodiments, the capacitor 256 comprises another suitable type of capacitor, such as metal-oxide-semiconductor (MOS) capacitor.

The capacitor 256 is electrically coupled to the electrode 220 through the via 224, and the capacitor 256 is in series with the P-I-N diode, which reduces the overall capacitance of the waveguide PD 200, according to an embodiment.

Because decreasing the thickness of the P-I-N diode increases a junction capacitance of the waveguide PD (which tends to decrease the bandwidth of the P-I-N diode) the capacitor 256 is provided to reduce the overall capacitance of the waveguide PD 200 (and thus counteracts the negative bandwidth effect of the increased junction capacitance caused by the decreased thickness of the P-I-N diode), according to an embodiment.

The waveguide PD 200 also includes one or more metal traces 268 that are electrically coupled to the one or more electrodes 240 through the vias 244, 248. The one or more metal traces 268 are electrically coupled to the waveguide 208 through vias 270, 272, which comprise a suitable electrically conductive material such as metal.

In some embodiments, to further counteract the increase of the junction capacitance when the thickness of the light absorption region 212 is reduced, a length of the light absorption region 212 and/or a width of the light absorption region 212 is reduced as compared to other implementations. But, as discussed above, decreasing the length and/or the width of the light absorption region 212 tends to reduce responsivity of a waveguide PD with regard to light-to-current conversion. In particular, because the length and/or the width of the light absorption region 212 is reduced, there is less area of the light absorption region 212 available to absorb light and/or there is less area available for connecting to the vias 258, 260 to provide electrical coupling to the capacitor 256.

Therefore, in some embodiments, the waveguide 208 is configured as a multi-mode interference (MMI) waveguide, the MMI waveguide 208 being configured to provide one or more regions of focused light energy within an area of the MMI waveguide 208 below the light absorption region 212, i.e., overlaps with the light absorption region 212.

FIG. 2C is a simplified block diagram (top view) of the waveguide PD 200 in an embodiment in which the waveguide 208 is configured as an MMI waveguide, according to an embodiment. Some layers and/or components of the waveguide PD 200 are not shown in FIG. 2C to avoid obscuring elements of the waveguide PD 200 that are present in FIG. 2C.

In the embodiment illustrated in FIG. 2C, a width w₁ and/or a length l₁ of the absorption region 212 is reduced as compared to other implementations of a waveguide PD. As a result, there is less area of the light absorption region 212 available to absorb light and/or there is less area available for connecting to the vias 258, 260 to provide electrical coupling to the capacitor 256.

The MMI waveguide 208 has a width w₂ and a length l₂. The width w2 of the MMI waveguide 208 is selected so as to cause an optical wave from the input waveguide 204 to form an interference pattern 280 having areas of interference maxima 284. For a symmetrical MMI waveguide 208, at least some of the interference maxima 284 are formed along an axis of symmetry which runs vertically in FIG. 2C, i.e., from the input waveguide 204 to under the absorption region 212. The interference pattern 280 depicted in FIG. 2C is not intended to show an accurate interference pattern 280 but merely to indicate existence of the interference pattern 280 for the purpose of visualization.

At least some of the interference maxima 284 are located in an area of overlap with the absorption region 212, i.e., under the absorption region 212. As a high portion of the energy in the guided optical wave within the MMI waveguide 208 is concentrated (i.e., focused) in interference maxima 284, more optical energy is absorbed by the absorption region 212 as compared to implementations in which the waveguide 208 is not configured as an MMI waveguide and in which the width w₁ and/or the length l₁ of the absorption region 212 is reduced.

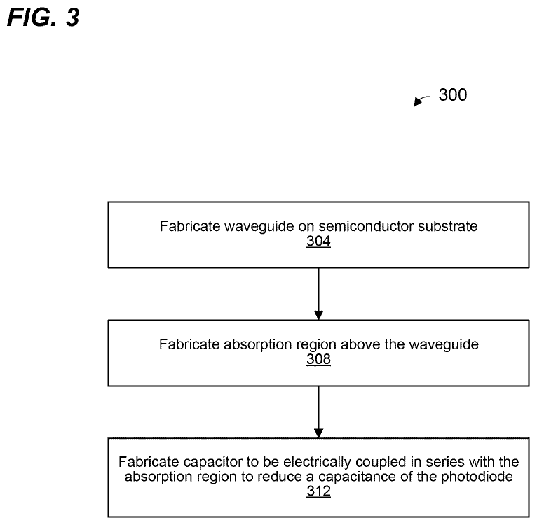

FIG. 3 is a flow diagram of an example method 300 for manufacturing a waveguide PD, according to an embodiment. The method 300 is performed to manufacture the example waveguide PD of FIGS. 2A-B and/or the example waveguide PD of FIG. 2C, according to various embodiments, and the method 300 is described with reference to FIGS. 2A-C for explanatory purposes. In other embodiments, the method 300 is used to manufacture another suitable photodiode different than the example waveguide PDs of FIGS. 2A-C. In other embodiments, the example waveguide PD of FIGS. 2A-B and/or the example waveguide PD of FIG. 2C are manufactured using a suitable method different than the example method 300.

At block 304, a waveguide is fabricated on a semiconductor substrate. The waveguide is configured to receive a modulated optical signal that conveys data, in an embodiment. Fabricating the waveguide at block 304 comprises fabricating the waveguide on an SOI substrate, in an embodiment. Fabricating the waveguide at block 304 comprises fabricating the waveguide on another suitable substrate different than SOI, in another embodiment.

Fabricating the waveguide at block 304 comprises fabricating the waveguide 208 of FIGS. 2A-B and/or the MMI waveguide 208 of FIG. 2C, according to various embodiments.

At block 308, an absorption region is fabricated above the waveguide. Fabricating the absorption region at block 308 comprises fabricating the absorption region comprising a Ge material, in an embodiment. Fabricating the absorption region at block 308 comprises fabricating the absorption region to have another suitable material different than a Ge material, in another embodiment.

Fabricating the absorption region at block 308 comprises fabricating the absorption region 212 of FIGS. 2A-B and/or the absorption region 212 of FIG. 2C, according to various embodiments.

At block 312, a capacitor is fabricated to be electrically coupled in series with the absorption region to reduce a capacitance of the photodiode as compared to a scenario in which the capacitor is omitted from the photodiode. For example, the capacitor at block 312 comprises fabricating the capacitor 256 of FIG. 2B, according to an embodiment.

Fabricating the capacitor at block 312 comprises fabricating an MIM capacitor, in an embodiment. Fabricating the capacitor at block 312 comprises fabricating an MOM capacitor, in another embodiment.

In another embodiment, fabricating the waveguide at block 304 comprises fabricating the waveguide as an MMI waveguide. In another embodiment in which the waveguide fabricated at block 304 is an MMI waveguide, fabricating the MMI waveguide comprises: fabricating the MMI waveguide to be configured to generate an interference pattern having one or more local maxima located underneath the absorption region. In another embodiment in which the waveguide fabricated at block 304 is an MMI waveguide, the method 300 further comprises: fabricating a first via that electrically couples the absorption region to the capacitor; and fabricating a second via that electrically couples the absorption region to the capacitor; wherein fabricating the MMI waveguide comprises fabricating the MMI waveguide to be configured to generate an interference pattern having the one or more local maxima located between the first via and the second via.

In another embodiment, the method 300 further comprises: fabricating an electrode to be electrically coupled to the absorption region such that the capacitor is electrically coupled in series between the electrode and the absorption region to reduce the capacitance of the photodiode as compared to the scenario in which the capacitor is omitted from the photodiode. In another embodiment in which the method 300 includes fabricating the electrode, fabricating the capacitor at block 312 comprises fabricating the capacitor to be above the absorption region and below the electrode.

Embodiment 1: An optical communication receiver, comprising: a photodiode configured to receive a modulated optical signal conveying data and convert the modulated optical signal to an electrical signal. The photodiode includes: a waveguide configured to receive the modulated optical signal; an absorption region above the waveguide; and a capacitor electrically coupled in series with the absorption region to reduce a capacitance of the photodiode as compared to a scenario in which the capacitor is omitted from the photodiode. The optical communication receiver further comprises signal processing circuitry coupled to the photodiode, the signal processing circuitry configured to process the electrical signal to extract and output the data.

Embodiment 2: The optical communication receiver of embodiment 1, wherein the photodiode further includes: an electrode electrically coupled to the absorption region; wherein the capacitor is electrically coupled in series between the absorption region and the electrode to reduce the capacitance of the photodiode as compared to the scenario in which the capacitor is omitted from the photodiode.

Embodiment 3: The optical communication receiver of embodiment 2, wherein the capacitor is above the absorption region and below the electrode.

Embodiment 4: The optical communication receiver of any of embodiments 1-3, wherein the capacitor comprises a metal-insulator-metal (MIM) capacitor.

Embodiment 5: The optical communication receiver of any of embodiments 1-3, wherein the capacitor comprises a metal-oxide-metal (MOM) capacitor.

Embodiment 6: The optical communication receiver of any of embodiments 1-5, wherein the waveguide is configured as a multi-mode interference (MMI) waveguide.

Embodiment 7: The optical communication receiver of embodiment 6, wherein the MMI waveguide is configured to generate an interference pattern having one or more local maxima located underneath the absorption region.

Embodiment 8: The optical communication receiver of embodiment 7, wherein the photodiode further includes: a first via that electrically couples the absorption region to the capacitor; and a second via that electrically couples the absorption region to the capacitor; wherein the MMI waveguide is configured to generate an interference pattern having the one or more local maxima located between the first via and the second via.

Embodiment 9: The optical communication receiver of any of embodiments 1-8, wherein the signal processing circuitry comprises: a transimpedance amplifier configured to convert an analog electrical signal output by the photodiode from an analog current signal to an analog voltage signal.

Embodiment 10: The optical communication receiver of any of embodiments 1-9, wherein the signal processing circuitry further comprises: an analog-to-digital converter configured to convert the analog voltage signal to a digital signa; and digital signal processing circuitry configured to process the digital signal to extract the data.

Embodiment 11: A method for manufacturing a photodiode, comprising: fabricating a waveguide on a semiconductor substrate, the waveguide configured to receive a modulated optical signal that conveys data; fabricating an absorption region above the waveguide; and fabricating a capacitor that is electrically coupled in series with the absorption region to reduce a capacitance of the photodiode as compared to a scenario in which the capacitor is omitted from the photodiode.

Embodiment 12: The method for manufacturing of embodiment 11, further comprising: fabricating an electrode to be electrically coupled to the absorption region such that the capacitor is electrically coupled in series between the electrode and the absorption region to reduce the capacitance of the photodiode as compared to the scenario in which the capacitor is omitted from the photodiode.

Embodiment 13: The method for manufacturing of embodiment 12, wherein fabricating the capacitor comprises: fabricating the capacitor to be above the absorption region and below the electrode.

Embodiment 14: The method for manufacturing of any of embodiments 11-13, wherein fabricating the capacitor comprises: fabricating a metal-insulator-metal (MIM) capacitor.

Embodiment 15: The method for manufacturing of any of embodiments 11-13, wherein fabricating the capacitor comprises: fabricating a metal-oxide-metal (MOM) capacitor.

Embodiment 16: The method for manufacturing of any of embodiments 11-15, wherein fabricating the waveguide comprises: fabricating a multi-mode interference (MMI) waveguide.

Embodiment 17: The method for manufacturing of embodiment 16, wherein fabricating the MMI waveguide comprises: fabricating the MMI waveguide to be configured to generate an interference pattern having one or more local maxima located underneath the absorption region.

Embodiment 18: The method for manufacturing of embodiment 17, further comprising: fabricating a first via that electrically couples the absorption region to the capacitor; and fabricating a second via that electrically couples the absorption region to the capacitor; wherein fabricating the MMI waveguide comprises fabricating the MMI waveguide to be configured to generate an interference pattern having the one or more local maxima located between the first via and the second via.

Embodiment 19: A photodiode, comprising: a waveguide configured to receive the modulated optical signal; an absorption region above the waveguide; and a capacitor electrically coupled in series with the absorption region to reduce a capacitance of the photodiode as compared to a scenario in which the capacitor is omitted from the photodiode.

Embodiment 20: The photodiode of embodiment 19, wherein the photodiode further includes: an electrode electrically coupled to the absorption region; wherein the capacitor is electrically coupled in series between the absorption region and the electrode to reduce the capacitance of the photodiode as compared to the scenario in which the capacitor is omitted from the photodiode.

Embodiment 21: The photodiode of embodiment 20, wherein the capacitor is above the absorption region and below the electrode.

Embodiment 22: The photodiode of any of embodiments 19-21, wherein the capacitor comprises a metal-insulator-metal (MIM) capacitor.

Embodiment 23: The photodiode of any of embodiments 19-21, wherein the capacitor comprises a metal-oxide-metal (MOM) capacitor.

Embodiment 24: The photodiode of any of embodiments 19-23, wherein the waveguide is configured as a multi-mode interference (MMI) waveguide that generates an interference pattern having one or more local maxima located underneath the absorption region.

Embodiment 25: The photodiode of embodiment 24, wherein the MMI waveguide is configured to generate an interference pattern having one or more local maxima located underneath the absorption region.

Embodiment 26: The photodiode of embodiment 25, wherein the photodiode further includes: a first via that electrically couples the absorption region to the capacitor; and a second via that electrically couples the absorption region to the capacitor; wherein the MMI waveguide is configured to generate an interference pattern having the one or more local maxima located between the first via and the second via.

Embodiment 27: The photodiode of any of embodiments 19-26, wherein the photodiode is configured to convert a modulated optical signal conveying data to an electrical signal.

While the present invention has been described with reference to specific examples, which are intended to be illustrative only and not to be limiting of the invention, changes, additions and/or deletions may be made to the disclosed embodiments without departing from the scope of the invention.

What is claimed is:

1. An optical communication receiver, comprising:
a photodiode configured to receive a modulated optical signal conveying data and convert the modulated optical signal to an electrical signal, the photodiode including:
a waveguide configured to receive the modulated optical signal,
an absorption region above the waveguide, and
a capacitor electrically coupled in series with the absorption region to reduce a capacitance of the photodiode as compared to a scenario in which the capacitor is omitted from the photodiode; and
signal processing circuitry coupled to the photodiode, the signal processing circuitry configured to process the electrical signal to extract and output the data.

2. The optical communication receiver of claim 1, wherein the photodiode further includes:
an electrode electrically coupled to the absorption region;
wherein the capacitor is electrically coupled in series between the absorption region and the electrode to reduce the capacitance of the photodiode as compared to the scenario in which the capacitor is omitted from the photodiode.

3. The optical communication receiver of claim 2, wherein the capacitor is above the absorption region and below the electrode.

4. The optical communication receiver of claim 1, wherein the capacitor comprises a metal-insulator-metal (MIM) capacitor.

5. The optical communication receiver of claim 1, wherein the capacitor comprises a metal-oxide-metal (MOM) capacitor.

6. The optical communication receiver of claim 1, wherein the waveguide is configured as a multi-mode interference (MMI) waveguide.

7. The optical communication receiver of claim 6, wherein the MMI waveguide is configured to generate an interference pattern having one or more local maxima located underneath the absorption region.

8. The optical communication receiver of claim 7, wherein the photodiode further includes:
a first via that electrically couples the absorption region to the capacitor; and
a second via that electrically couples the absorption region to the capacitor;
wherein the MMI waveguide is configured to generate an interference pattern having the one or more local maxima located between the first via and the second via.

9. The optical communication receiver of claim 1, wherein the signal processing circuitry comprises:
a transimpedance amplifier configured to convert an analog electrical signal output by the photodiode from an analog current signal to an analog voltage signal.

10. The optical communication receiver of claim 1, wherein the signal processing circuitry further comprises:
an analog-to-digital converter configured to convert the analog voltage signal to a digital signa; and
digital signal processing circuitry configured to process the digital signal to extract the data.

11. A method for manufacturing a photodiode, comprising:
fabricating a waveguide on a semiconductor substrate, the waveguide configured to receive a modulated optical signal that conveys data;
fabricating an absorption region above the waveguide; and
fabricating a capacitor that is electrically coupled in series with the absorption region to reduce a capacitance of the photodiode as compared to a scenario in which the capacitor is omitted from the photodiode.

12. The method for manufacturing of claim 11, further comprising:
fabricating an electrode to be electrically coupled to the absorption region such that the capacitor is electrically coupled in series between the electrode and the absorption region to reduce the capacitance of the photodiode as compared to the scenario in which the capacitor is omitted from the photodiode.

13. The method for manufacturing of claim 12, wherein fabricating the capacitor comprises:
fabricating the capacitor to be above the absorption region and below the electrode.

14. The method for manufacturing of claim 11, wherein fabricating the capacitor comprises:
fabricating a metal-insulator-metal (MIM) capacitor.

15. The method for manufacturing of claim 11, wherein fabricating the capacitor comprises:
fabricating a metal-oxide-metal (MOM) capacitor.

16. The method for manufacturing of claim 11, wherein fabricating the waveguide comprises:
fabricating a multi-mode interference (MMI) waveguide.

17. The method for manufacturing of claim 16, wherein fabricating the MMI waveguide comprises:
fabricating the MMI waveguide to be configured to generate an interference pattern having one or more local maxima located underneath the absorption region.

18. The method for manufacturing of claim 17, further comprising:
fabricating a first via that electrically couples the absorption region to the capacitor; and
fabricating a second via that electrically couples the absorption region to the capacitor;
wherein fabricating the MMI waveguide comprises fabricating the MMI waveguide to be configured to generate an interference pattern having the one or more local maxima located between the first via and the second via.

19. A photodiode for converting a modulated optical signal conveying data to an electrical signal, comprising:
a waveguide configured to receive the modulated optical signal;
an absorption region above the waveguide; and
a capacitor electrically coupled in series with the absorption region to reduce a capacitance of the photodiode as compared to a scenario in which the capacitor is omitted from the photodiode.

20. The photodiode of claim 19, wherein the photodiode further includes:
an electrode electrically coupled to the absorption region;
wherein the capacitor is electrically coupled in series between the absorption region and the electrode to reduce the capacitance of the photodiode as compared to the scenario in which the capacitor is omitted from the photodiode.

21. The photodiode of claim 20, wherein the capacitor is above the absorption region and below the electrode.

22. The photodiode of claim 19, wherein the waveguide is configured as a multi-mode interference (MMI) waveguide that generates an interference pattern having one or more local maxima located underneath the absorption region.
